(19) United States
(12) Patent Application Publication
(10) Pub. No.: US 2025/0210319 A1
(43) Pub. Date: Jun. 26, 2025

(54) ELECTRODE CONFIGURATIONS AND MAGNET CONFIGURATIONS FOR PROCESSING CHAMBERS, AND RELATED METHODS AND APPARATUS, FOR SEMICONDUCTOR MANUFACTURING

(71) Applicant: Applied Materials, Inc., Santa Clara, CA (US)

(72) Inventors: Ala MORADIAN, Sunnyvale, CA (US); Saurabh CHOPRA, Santa Clara, CA (US); Prashanth KOTHNUR, San Jose, CA (US); Ananth Nuggehalli BHOJ, Santa Clara, CA (US); Yunho KIM, Santa Clara, CA (US); Umesh M. KELKAR, Santa Clara, CA (US); Phillip STOUT, Santa Clara, CA (US); Zuoming ZHU, Sunnyvale, CA (US)

(21) Appl. No.: 18/391,176

(22) Filed: Dec. 20, 2023

(51) Int. Cl. H01J 37/32; C23C 16/458; C23C 16/505

(52) U.S. Cl. CPC H01J 37/32669; C23C 16/4586; C23C 16/505; H01J 37/32082; H01J 37/32568; H01J 2237/152; H01J 2237/327; H01J 2237/3321

(57) ABSTRACT

The present disclosure relates to electrode configurations and magnet configurations for processing chambers, and related methods and apparatus, for semiconductor manufacturing. In one or more embodiments, a processing chamber applicable for use in semiconductor manufacturing includes one or more sidewalls, a plate at least partially defining a processing volume, and a substrate support disposed in the processing volume. The processing chamber includes one or more heat sources operable to heat the processing volume, a first electrode disposed outwardly of the processing volume, and a second electrode coupled to the substrate support.

### BACKGROUND

### Field

The present disclosure relates to electrode configurations and magnet configurations for processing chambers, and related methods and apparatus, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Operations can also be limited with respect to application modularity. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance.

Therefore, a need exists for improved apparatuses and methods in semiconductor processing.

### SUMMARY

The present disclosure relates to electrode configurations and magnet configurations for processing chambers, and related methods and apparatus, for semiconductor manufacturing.

In one or more embodiments, a processing chamber applicable for use in semiconductor manufacturing includes one or more sidewalls, a plate at least partially defining a processing volume, and a substrate support disposed in the processing volume. The processing chamber includes one or more heat sources operable to heat the processing volume, a first electrode disposed outwardly of the processing volume, and a second electrode coupled to the substrate support.

In one or more embodiments, a processing chamber applicable for use in semiconductor manufacturing includes one or more sidewalls, a plate at least partially defining a processing volume, and a substrate support disposed in the processing volume. The processing chamber includes one or more heat sources operable to heat the processing volume, and a plurality of magnets configured to generate a magnetic field across at least a section of the processing volume.

In one or more embodiments, a method of substrate processing includes heating a substrate on a substrate support to a target temperature, where the substrate is disposed in a processing volume, flowing one or more process gases over the substrate, flowing a gas to the processing volume, and applying a power to the processing volume while flowing the gas to generate a plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic side cross-sectional view of a processing chamber, according to one or more embodiments.

FIG. 3 is a schematic side cross-sectional view of a processing chamber, according to one or more embodiments.

FIG. 4 is a schematic side cross-sectional view of a processing chamber, according to one or more embodiments.

FIG. 5 is a schematic side cross-sectional view of a processing chamber, according to one or more embodiments.

FIG. 6 is a schematic side cross-sectional view of a processing chamber, according to one or more embodiments.

FIG. 7A is a schematic view of a magnet set, according to one or more embodiments.

FIG. 7B is a schematic view of a magnetic ring, according to one or more embodiments.

FIG. 8 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to electrode configurations and magnet configurations for processing chambers, and related methods and apparatus, for semiconductor manufacturing. In one or more embodiments, a magnetic field is used to filter and/or direct at least part of a plasma. In one or more embodiments, the plasma is used to activate gases in relatively low temperature epitaxial deposition operations.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

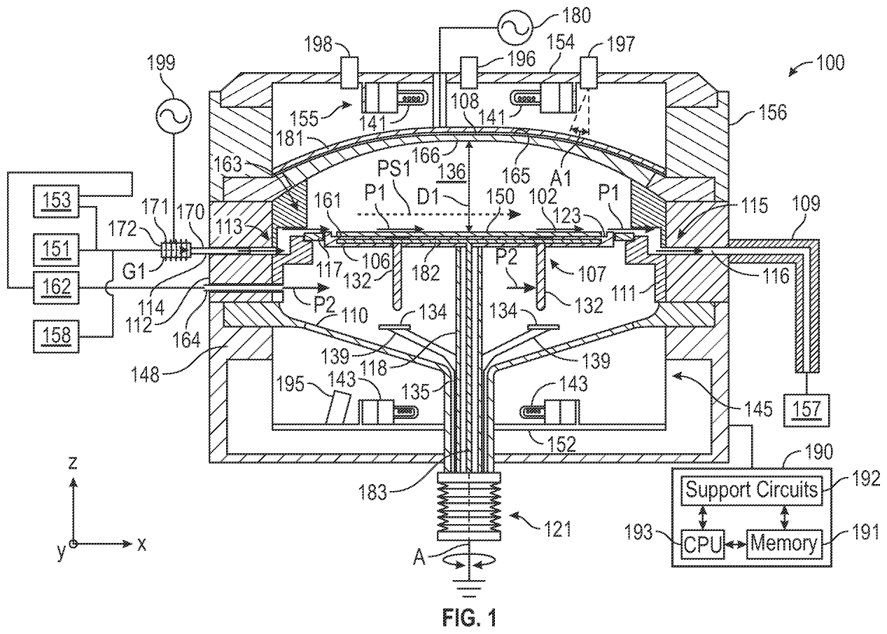

FIG. 1 is a schematic side cross-sectional view of a processing chamber 100, according to one or more embodiments. The processing chamber 100 is a deposition chamber. In one or more embodiments the processing chamber 100 is applicable for semiconductor manufacturing. In one or more embodiments, the processing chamber 100 is an epitaxial deposition chamber. The processing chamber 100 is utilized to grow an epitaxial film on a substrate 102, and the processing chamber 100 is used to supply a plasma for plasma operations (such as plasma-assisted film deposition, supply of ions into the substrate 102, pre-cleaning of the substrate 102, etching of the substrate 102, and/or cleaning of the processing chamber 100). In one or more embodiments, the processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a plate 108, one or more heat sources 141, 143, and a window 110 (e.g., a lower window, for example a lower dome). In one or more embodiments, the window 110 is formed of an energy transmissive material, such as transparent quartz. In one or more embodiments, the plate 108 is a window, such as an upper window. In one or more embodiments, the plate 108 is an upper dome. In one or more embodiments, the plate 108 is formed of an energy transmissive material, such as transparent quartz. In one or more embodiments, the plate 108 if is formed at least partially of an opaque material such as opaque quartz (e.g., white quartz and/or grey quartz), black quartz, silicon carbide (SiC), graphite coated with SiC, and/or sapphire. In one or more embodiments, the plate 108 is a flat plate. In one or more embodiments, at least part of the plate 108 is curved. The one or more heat sources 141, 143 include a plurality of lower heat sources 143 operable to heat a processing volume 136 from one side of the substrate 102 (e.g., from below the substrate 102). In one or more embodiments, the one or more heat sources 141, 143 include a plurality of upper heat sources 141 operable to heat the processing volume 136 from a second side of the substrate 102 (e.g., from above the substrate 102). The chamber body and the plate 108 at least partially define the processing volume 136. In one or more embodiments, the lower heat sources 141, 143 include lamps (such as halogen lamps or UV lamps). The present disclosure contemplates that other heat sources may be used (in addition to or in place of the lamps) for the various heat sources described herein. For example, resistive heaters, microwave powered heaters, light emitting diodes (LEDs), lasers (e.g., laser diodes), and/or or any other suitable heat source singly or in combination may be used for the various heat sources described herein. In one or more embodiments the upper heat sources 141 are omitted such that the substrate 102 is heated from a back side using the lower heat sources 143.

The substrate support 106 is disposed in the processing volume 136 and between the plate 108 and the window 110. The substrate support 106 is disposed between the one or more heat sources 141, 143, and the substrate support 106 supports the substrate 102. The plate 108 is disposed between the substrate support 106 and a lid 154 of the processing chamber 100. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The upper heat sources are disposed between the lid 154 and the plate 108. The plurality of lower heat sources 143 are disposed between the window 110 and a floor 152. The plurality of lower heat sources 143 form a portion of a lower heat source module 145.

The processing volume 136 and a purge volume 138 are between the plate 108 and the window 110. The processing volume 136 and the purge volume 138 are part of an internal volume of the processing chamber 100. One or more liners 111, 163 are disposed inwardly of the chamber body.

The substrate support 106 includes a top surface on which the substrate 102 is disposed. The substrate support 106 is coupled to a shaft 118. In one or more embodiments, the substrate support 106 is coupled to the shaft 118 through one or more arms 119 coupled to the shaft 118. The shaft 118 is coupled to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 are part of an inject portion 113 of the chamber body, and the one or more gas exhaust outlets 116 are part of an exhaust portion 115 of the chamber body. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The pre-heat ring 117 can include a complete ring or one or more ring segments. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

One or more gas sources 158 are also fluidly connected to the gas inlet(s) 114. The one or more gas sources 158 supply one or more plasma precursor gases that can be ignited into a plasma. A flow housing 171 is disposed at least partially outward of the flow module 112 and is fluidly connected to the flow module 112 through one or more flow channels 170 disposed between the flow housing 171 and the gas inlet 114. One or more radio frequency (RF) coils 172 is disposed at least partially around the flow housing 171. For example, the one or more RF coils 172 can be wound around the flow housing 171. As a gas G1 flows from the gas source 158 and through the flow housing 171, the one or more RF coils 172 ignite the gas G1 into a plasma PS1 which then flows through the one or more flow channels 170 and into the gas inlet 114. The one or more flow channels 170 can be formed, for example, in one or more gas boxes. RF current flows through the one or more RF coils 172 while the gas G1 flows, which applies a voltage across the gas G1 to ignite the gas G1 into the plasma PS1. The present disclosure contemplates that an ion filter can be positioned such that the ion filter filters ions from the plasma PS1 prior to the plasma PS1 flowing over the substrate 102. The ion filter can include a conductive material including, for example, silicon carbide (SiC), molybdenum, tungsten, stainless steel, and/or aluminum (such as anodized aluminum). The ion filter can include an ion blocker plate. The one or more gases G1 supplied using the one or more gas sources 158 can include one or more precursor gases to generate plasma such as Xenon (Xe₂), Neon (Ne₂), Helium (He₂) Fluorine (F₂), Krypton (Kr2), and/or any mixtures of the thereof (such as Krypton Fluoride (KrF). In one or more embodiments, the gas G1 includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one or more embodiments, the gas G1 includes one or more dopant gases, such as germane, diborane, and/or phosphorous. Other gases are contemplated for the gas G1. Other precursor gases are contemplated to generate the plasma PS1.

The processing chamber 100 includes a first electrode 181 between the plate 108 and the lid 154. In one or more embodiments, the first electrode 181 is disposed at a gap from the plate 108. The first electrode 181 can be at least partially supported by the lid 154 and/or the upper body 156. In one or more embodiments, the first electrode 181 is at least partially supported by an upper surface 165 of the plate 108. In one or more embodiments, the first electrode 181 has a mesh structure to allow at least part of electromagnetic radiation from the upper heat sources 141 to propagate through the mesh structure. In one or more embodiments, the first electrode 181 has a solid cross section. In one or more embodiments the first electrode 181 is made of an opaque material. In one or more embodiments the upper heat sources 141 are omitted. The first electrode 181 is electrically coupled to an RF power source 180. A second electrode 182 is coupled the substrate support 106. In one or more embodiments, the second electrode 182 is embedded in the substrate support 106. The substrate support 106 is grounded by a conductive rod 183 that connects the substrate support 106 to ground. In or more embodiments RF current flows from the first electrode 181, to the second electrode 182, and to ground through the conductive rod 183. In one or more embodiments, the RF current flows through one or more of: the plate 108, at least a section of the processing volume 136 and/or inner surface(s) of the liner 163. The gas G1 flows from into the processing volume 136 through the gas inlet 114. As the gas G1 flows into the processing volume 136 the gas G1 is ignited in a capacitively coupled plasma (CCP) manner by the RF current flowing between the first electrode 181 and the second electrode 182. The present disclosure contemplates that the RF current flow can be reversed such that the RF current can flow from the second electrode 182 and to the first electrode 181. The RF power ignites the gas G1 into a plasma PS1 as the gas G1 is passing through the processing volume 136. The size and position of the first electrode 181 and the second electrode 182 as well as the intensity the RF power applied to the first electrode 181 may be adjusted to determine where in the processing volume 136 the gas G1 becomes a plasma PS1, and the intensity of the plasma PS1. In one or more embodiments, the gas G1 is ignited by the RF power supplied to the first electrode 181 in conjunction with the one or more RF coils 172 disposed at least partially about the flow housing 171. In one or more embodiments, the one or more RF coils 172 are unpowered or are omitted, and the plasma PS1 is generated using the first and second electrodes 181, 182.

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102. The substrate 102 is disposed at a distance D1 within a range of about 5 mm to about 30 mm relative to the lower surface 166 of the plate 108 during processing.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The present disclosure contemplates that the plasma PS1 and the one or more process gases P1 can flow simultaneously and/or sequentially with respect to each other. In one or more embodiments during the cleaning operation the gas G1 is flowed through the flow housing 171 simultaneously with the process gases P1 (the gas G1 can be flowed with the process gases P1 or separately from the process gases P1), or before or after the flowing of the one or more process gases P1. The plasma PS1 may flow into the processing volume 136 before the processing gas P1 to pre clean the substrate 102. The plasma may flow into the processing volume 136 after the process gases P1 in order to clean the processing volume 136 after deposition operations. In one or more embodiments, the gas G1 flows simultaneously with the process gases P1 through the flow housing 171. In more than one embodiments, and as described above, the gas G1 is ignited into the plasma PS1 in the processing chamber by the RF power from the RF power source 180 flowing between the first electrode 181 and the second electrode 182. The plasma PS1 and the process gases P1 may flow into the processing volume 136 simultaneously where the plasma PS1 may assist in the deposition operation by facilitating activation of the process gas(es) P1 (e.g., by breaking bonds of the process gas(es) P1. The present disclosure contemplates that a voltage and/or a frequency of RF power applied to the one or more RF coils 172 and/or the first electrode 181 can be varied and/or pulsed. The frequency can involve a single frequency or multiple frequencies. The multiple frequencies can be combined. The processing chamber 100 includes one or more sensor devices 195, 196, 197, 198 (e.g., metrology sensors, and/or temperature sensors) configured to measure parameter(s) (e.g., temperature(s)) within the processing chamber 100 and/or metrology parameter(s) of the substrate 102). In one or more embodiments, the one or more sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, one or more of the sensor devices 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. For example, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one or more embodiments, one or more of the sensor devices 195, 196, 197, 198 include a residual gas analyzer, an optical emission spectrometer, an enthalpy probe, a Langmuir probe, Faraday cup, and/or an absorption spectrometer.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

The present disclosure contemplates that all sensor devices can be disposed above the plate 108 and/or on or adjacent to the lid 154. For example, the one or more lower sensor devices 195 can be omitted.

Each sensor device 195, 196, 197, 198, can be a single-wavelength sensor device or a multi-wavelength (such as dual-wavelength) sensor device. In one or more embodiments, the processing chamber 100 includes any one, any two, or any three of the four illustrated sensor devices 195, 196, 197, 198. In one or more embodiments, the processing chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the pre-heat ring 117, the substrate support 106, and/or the liners 111, 163. As an example, one or more sensor devices 195, 196, 197, 198 can measure temperatures of the substrate 102 and/or the pre-heat ring 117, and power to the one or more heat sources 141, 143 and/or the energy source 176 can be controlled based on the measured temperatures (e.g., using a feedback control). As described the one or more sensor devices can include, for example pyrometers. In one or more embodiments, one or more thermocouples (e.g., proximity thermocouples) can be used in addition to or in place of the pyrometers, and power to the one or more heat sources 141, 143 and/or the energy source 176 can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power supplied to the one or more heat sources 141, 143, the one or more RF coils 172, and/or the first electrode 181, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations (such as operations of the method 800) described herein. The instructions stored on the memory, when executed, cause one or more of the operations (such as operations of the method 800) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heat sources 141, 143 and/or the energy source 176, the deposition, the cleaning, the rotational position, the heating, and gas flow through the processing chamber 100 by providing an output to the controls for the sensor devices 195, 196, 197, 198, the one or more heat sources 141, 143 and/or the energy source 176, the process gas source 151, the purge gas source 162, the motion assembly 121, and/or the exhaust pump 157.

During processing, in one or more embodiments, the substrate 102 is heated to a target temperature of 400 degrees Celsius or higher, or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is less than 500 degrees Celsius. In one or more embodiments, the target temperature for the substrate 102 is 400 degrees Celsius or less, such as less than 200 degrees Celsius (for example about 150 degrees Celsius).

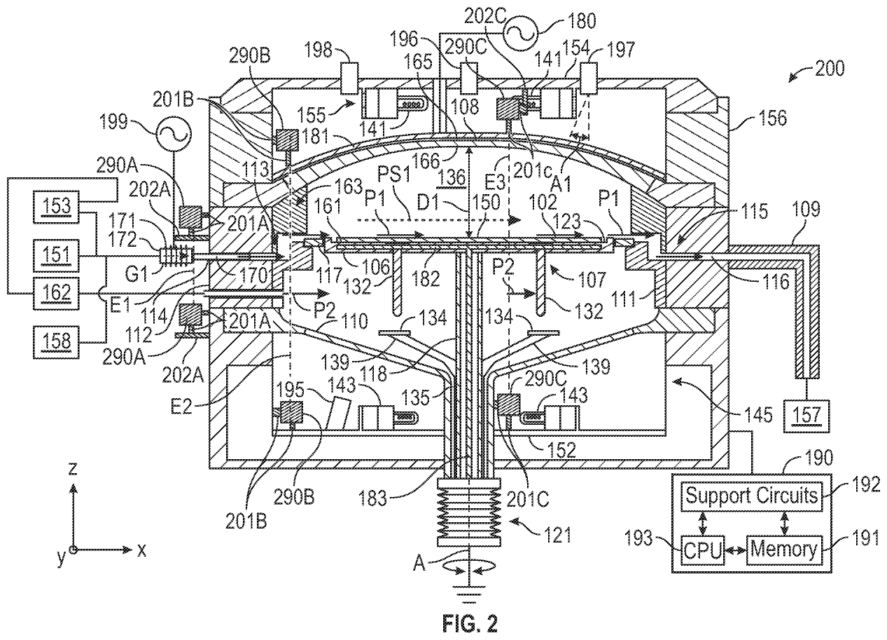

FIG. 2 is a schematic side cross-sectional view of a processing chamber 200 according to one or more embodiments. The processing chamber 200 is similar to processing chamber 100 shown in FIG. 1 and includes one or more aspects, features, components, operations, and/or properties thereof.

FIG. 2 incudes a plurality of magnet sets 290A, 290B, 290C, one or more actuators 201 (a plurality is shown), and one or more actuator supports 202 (a plurality is shown). In one or more embodiments the magnets of the magnet sets 290A, 290B, 290C are used to generate a magnetic field to direct and/or filter ions and/or electrons. For example the magnetic field can filter ions from the plasma PS1, direct ions of the plasma PS1 toward the substrate 102, and/or slow down electrons (e.g. of the RF current) to facilitate plasma generation. At least one of the plurality of magnets is coupled to the one or more actuators 201 operable to move the respective magnet(s). In one or more embodiments, the plurality of magnets of the magnet sets 290A, 290B, and 290C are coupled to a plurality of actuators 201A, 201B, and 201C. The actuators 201A, 201B, and 201C are coupled directly to processing chamber 200 or are coupled to one or more actuator supports 202A, 202C. The actuators 201A, 201B, and 201C are moveable and allow for the positions of the magnets of the magnet sets 290A, 290B, and 290C to be adjusted for plasma processing, which can adjust the processing that uses the plasma PS1. In one or more embodiments, the magnets of each magnet set 290A, 290B, 290C are independently movable relative to each other. The magnets of the magnet sets 290A, 290B, 290C can be permanent or non-permanent magnets. The magnets of the magnet sets 290A, 290B, 290C can include on or more neodymium iron boron magnets, samarium cobalt magnets, alnico magnets, and/or any combination thereof. In one or more embodiments, non-permanent magnet(s) respectively include an electromagnetic coil operable to flow a current (e.g. a direct current) therethrough to generate the magnetic field(s). The magnets can include magnet materials for temperatures above 300 degrees Celsius, such as 400 degrees Celsius or higher. Other magnet materials are contemplated. The magnets of the magnet sets 290A, 290B, 290C can be fixed in position.

The magnet sets 290A, 290B, 290C respectively include one or more magnets for each set. In one or more embodiments the magnet sets 290A, 290B, and 290C respectively include four curved (e.g., arcuate) sections that form a ring. The magnets of the magnet sets 290A, 290B, and 290C can include any number of curved sections that form a ring, such as three curved sections, two curved sections, and one curved section forming a ring. In one or more embodiments, the magnets of the magnet sets 290A, 290B, 290C generate a magnetic field or a plurality of magnetic fields E1, E2, E3.

In one or more embodiments a first magnet set 290A is positioned at least partially around the flow housing 171 outside of the processing chamber 200. The first magnet set 290A generates a magnetic field E1 that is about perpendicular to the flow of the plasma PS1 that is ignited in the flow housing 171. The magnetic field E1 is generated at an angle (e.g., about perpendicularly or at another angle) relative to a gas flow path of the gas G1. The magnetic field E1 can filter or direct (e.g. slow) plasma ions or RF electrons. In one or more embodiments, the angled magnetic field E1 filters ions from the plasma PS1 without the use of a physical filter (such as a perforated plate) and/or slows RF electrons to adjust processing.

In one or more embodiments, a magnetic field E2 is generated across one or more flow openings defined at least partially by the liner(s) 111, 163. A second magnet set 290B generates the magnetic field E2 that is angled (e.g., about perpendicularly or at another angle) relative to a gas flow path of the gas G1. The magnetic field E2 can filter or direct (e.g. slow) plasma ions or RF electrons. In one or more embodiments a magnetic field E3 is generated across at least a section of the processing volume 136. The magnetic field E3 is angled (e.g., about perpendicularly or at another angle) relative to a gas flow path of the gas G1. The magnetic field E2 can filter or direct (e.g. slow) plasma ions or RF electrons. A third magnet set 290C generates the magnetic field E3. In one or more embodiments, the magnetic field E3 is angled (e.g., about perpendicularly or at another angle) to the flow of the plasma PS1 in the processing volume 136. In one or more embodiments any of the previously described embodiments can be combined with one another. The second magnet set 290B is disposed at least partially about the liner(s) 111, 163, the plate 108, and the window 110. The third magnet set 290C is disposed at least partially about the plate 108 and the window 110.

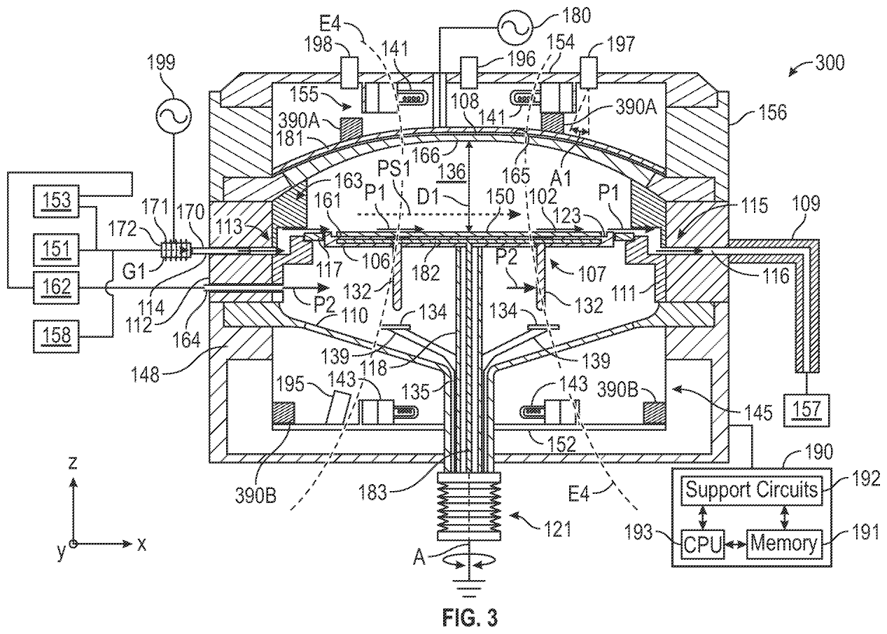

FIG. 3 is a schematic side cross-sectional view of a processing chamber 300, according to one or more embodiments. The processing chamber 300 is similar to processing chamber 100 shown in FIG. 1 and/or the processing chamber 200 shown in FIG. 2 and includes one or more aspects, features, components, operations, and/or properties thereof.

The processing chamber 300 includes a plurality of magnets 390A and 390B generating a magnetic field. In one or more embodiments, a second magnet set 390B is disposed radially outwardly of a first magnet set 390A to generate a magnetic field E4 that is curved. The magnetic field E4 is angled relative to the plasma PS1 flow to filter or direct (e.g., slow) ions and/or RF electrons. For example, the ions can be directed toward the substrate 102. In one or more embodiments the magnets 390A and 390B include a plurality of curved sections as previously described. In one or more embodiments, the magnets 390A and 3490B are coupled to a plurality of actuators 201 as described in FIG. 2.

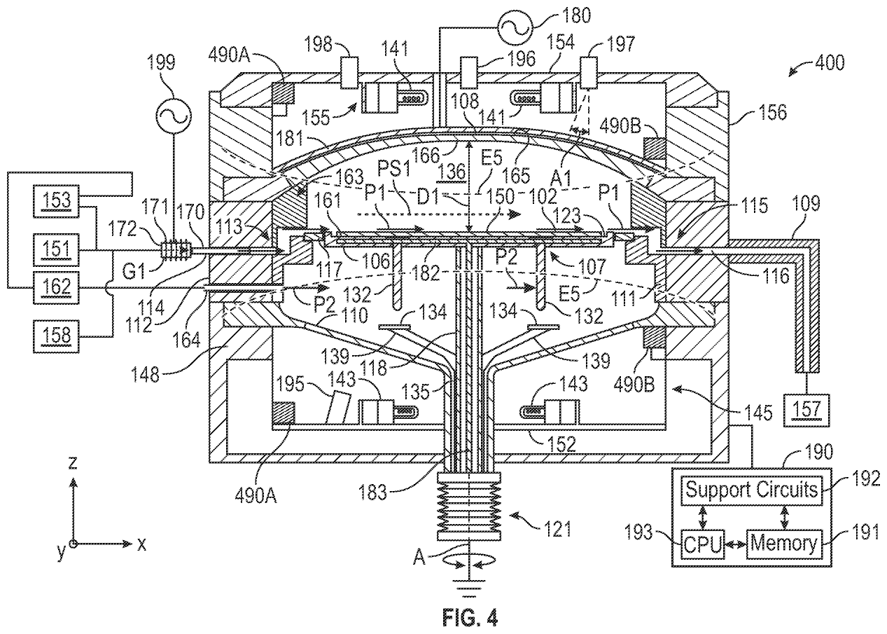

FIG. 4 is a schematic side cross-sectional view of a processing chamber 400, according to one or more embodiments. The processing chamber 400 is similar to the processing chamber 100 shown in FIG. 1, the processing chamber 200 shown in FIG. 2, and/or the processing chamber 300 in FIG. 3 and includes one or more aspects, features, components, operations, and/or properties thereof.

The processing chamber 400 includes a plurality of magnets 490A and 490B generating a magnetic field. In one or more embodiments a first magnet set 490A is disposed radially outwardly of a second magnet set 490B to generate a magnetic field E5 that is curved. The magnetic field E5 is about parallel to the plasma flow PS1. The magnetic field E5 filters or directs (e.g., slow) ions and/or RF electrons. In one or more embodiments, the magnets 490A and 490B include a plurality of curved sections as previously described. In one or more embodiments the magnets 490A and 490B are coupled to a plurality of actuators 201 as described in FIG. 2.

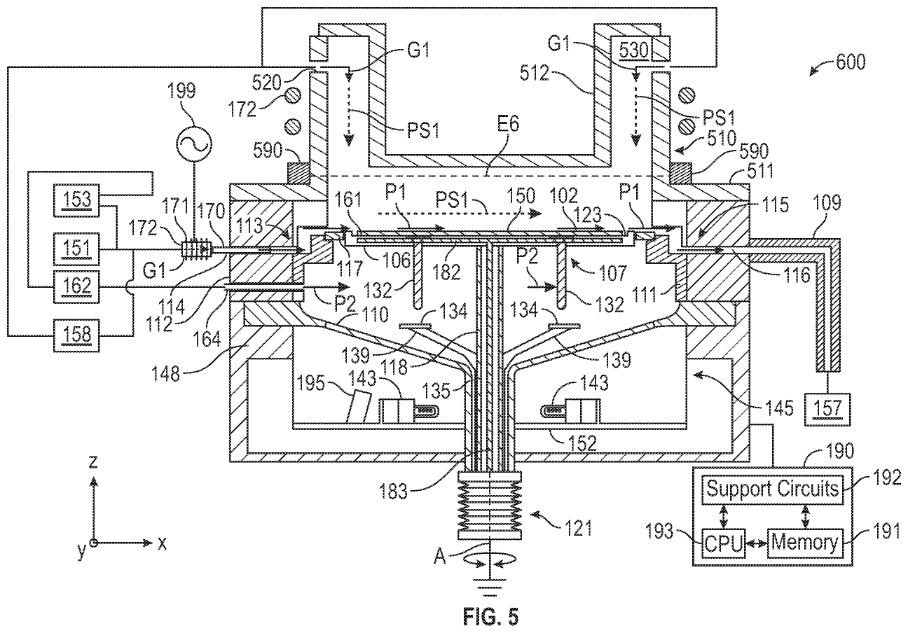

FIG. 5 is a schematic side cross-sectional view of a processing chamber 500, according to one or more embodiments. The processing chamber 500 is similar to the processing chamber 100 shown in FIG. 1, the processing chamber 200 shown in FIG. 2, the processing chamber 300 in FIG. 3, and/or the processing chamber 400 in FIG. 4 and includes one or more aspects, features, components, operations, and/or properties thereof.

The processing chamber 500 includes a lid assembly 510 including an outer wall 511, an inner wall 512, and a magnet set 590 of one or more magnets disposed at least partially around the outer wall 511. The processing chamber 500 includes one or more RF coils 172 disposed at least partially around the outer wall 511, one or more gas inlets 520, a lid volume 530, and a magnetic field E6.

In one or more embodiments, the gas G1 is flowed into the lid assembly 510 through the gas inlet(s) 520 and into the lid volume 530 defined by the inner wall 511 and the outer wall 512. As the gas G1 flows through the lid volume 530, the gas G1 is ignited by RF power through the one or more RF coils 172 into the plasma PS1. The magnet 590 generates the magnetic field E6. The magnetic field E6 is generated at an angled (e.g., about perpendicularly or at another angle) relative to a gas flow path of the gas G1 through the lid volume 530 to filter or direct (e.g., slow) ions and/or RF electron flow.

In one or more embodiments, a process gas P1 may flow simultaneously with the gas G1 into the lid assembly volume for plasma assisted deposition. In one or more embodiments the gas G1 is simultaneously flowed through the flow housing 171 in conjunction with the gas G1 flowing through the lid assembly 510. In one or more embodiments the magnet set 590A includes a plurality of curved sections as previously described. In one or more embodiments the magnets of the magnet set 590 are coupled to a plurality of actuators 201 as described in FIG. 2. The present disclosure contemplates that the gas inlets 114, the one or more RF coils 172, and the flow housing 171 shown in FIG. 5 can be omitted, and the gas G1 and the process gas(es) P1 can flow through the one or more gas inlets 520 and through the lid volume 530.

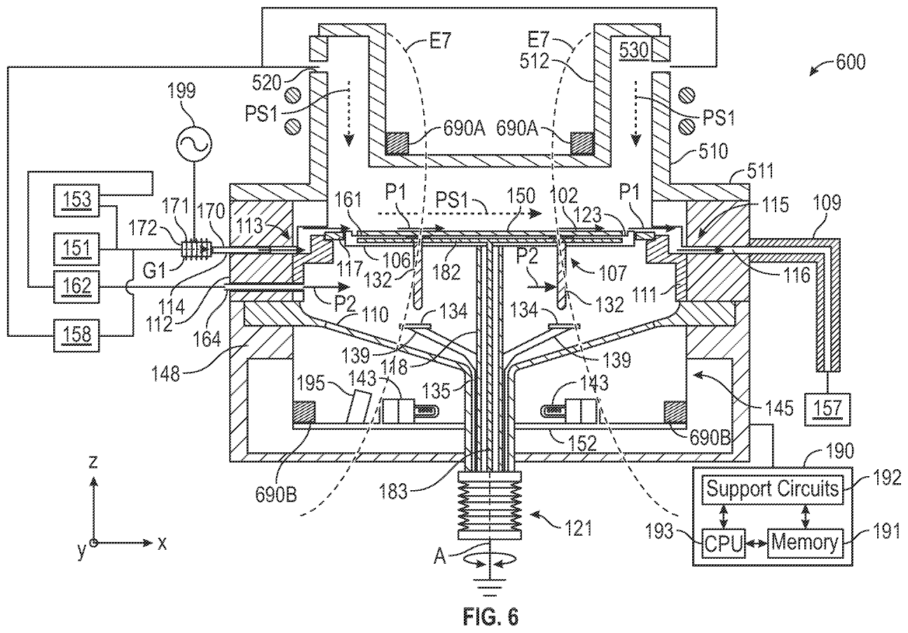

FIG. 6 is a schematic side cross-sectional view of a processing chamber 600, according to one or more embodiments. Processing chamber 600 is similar to processing chamber 500 shown in FIG. 5, and includes one or more aspects, features, components, operations, and/or properties thereof.

In one or more embodiments a first magnet set 690A of one or more magnets is disposed inwardly of the inner wall 512. A second magnet set 690B of one or more magnets is disposed at the bottom of the processing chamber 600 (e.g., on the floor 152). The second magnet set 690B is disposed radially outwardly of the first magnet set 690A. The magnets 690A and 690B generate a magnetic field E7 that is curved. The magnetic field E7 is about parallel to the plasma flow PS1 to filter or direct (e.g., slow) ions and/or RF electrons. In one or more embodiments, the parallel magnetic field E7 directs ions of the plasma PS1 toward the substrate 102. In one or more embodiments the magnet sets 690A and 690B respectively include a plurality of curved sections as previously described. In one or more embodiments the magnets 690A and 690B are coupled to a plurality of actuators 201 as described in FIG. 2.

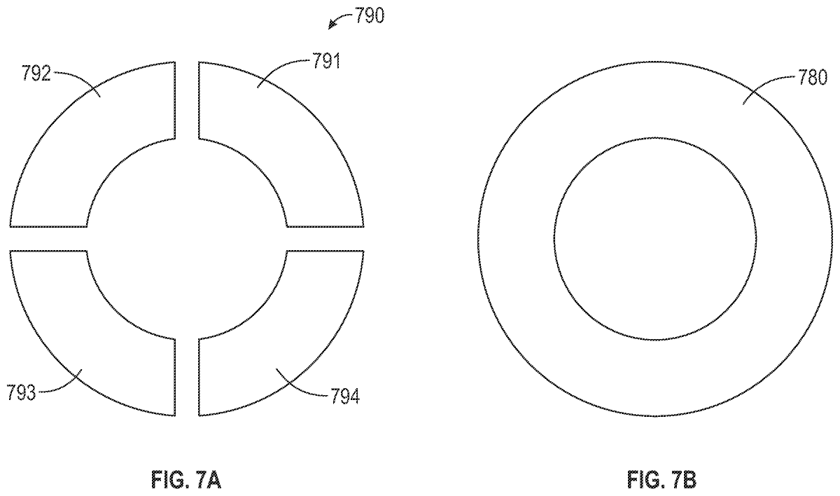

FIG. 7A is a schematic view of a magnet set 790, according to one or more embodiments. The magnets of the magnet set 790 can similar to any of the magnets previously described and the magnet set 790 includes 4 curved sections 791-794 that together form at least part of a ring. The magnet set 790 could be made up of any number of curved sections such as 5 curved sections, 3 curved sections, 2 curved sections, or one complete curved section forming a magnetic ring.

The view of the set of magnets 790 can be, for example, a left side view of the first magnet set 290A shown in FIG. 2, a top view of the first magnet set 390A shown in FIG. 3, a left side view of the first magnet set 490A shown in FIG. 4, a top view of the magnet set 590 shown in FIG. 5, and/or a top view of the first magnet set 690A shown in FIG. 6.

FIG. 7B is a schematic view of a magnetic ring 780, according to one or more embodiments. The magnetic ring 780 can be used place of any one of the magnet sets described above.

The view of the magnetic ring 780 can be, for example, a left side view of the first magnet set 290A shown in FIG. 2, a top view of the first magnet set 390A shown in FIG. 3, a left side view of the first magnet set 490A shown in FIG. 4, a top view of the magnet set 590 shown in FIG. 5, and/or a top view of the first magnet set 690A shown in FIG. 6.

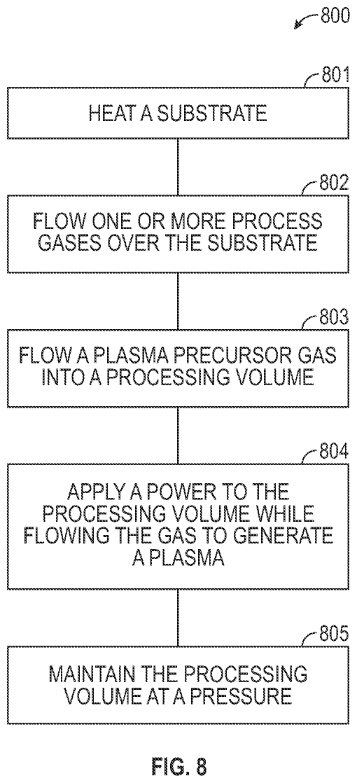

FIG. 8 is a schematic block diagram view of a method 800 of substrate processing for semiconductor manufacturing, according to one or more embodiments.

Operation 801 includes heating a substrate positioned on a substrate support of a processing chamber. The substrate is disposed in a processing volume of the processing chamber. The substrate can be heated from both sides or from one side of the substrate. The heating includes heating the substrate to a target temperature. In one or more embodiments, the target temperature is less than 500 degrees Celsius. In one or more embodiments, the target temperature is 400 degrees Celsius or less.

Operation 802 includes flowing one or more process gases over the substrate.

Operation 803 includes flowing a plasma precursor gas. The plasma precursor gas can be flowed toward the processing volume.

Operation 804 includes igniting the plasma precursor gas into a plasma by applying a power to a plasma precursor gas. The plasma can be ignited in a capacitively coupled plasma (CCP) manner or an inductively coupled plasma (ICP) manner. The plasma precursor gas can be ignited into the plasma in the processing volume 136 or in the flow housing 171. For example a plasma precursor gas can flow into the processing volume 136 shown in FIG. 1. An electrical power may then be applied to the electrode 181 disposed above the plate 108. In one or more embodiments, the plasma of operation 804 is supplied during the flowing of the one or more process gases of operation 802, and the plasma flows over the substrate. In one or more embodiments, the plasma of operation 804 is supplied before or after the flowing of the one or more process gases of operation 802.

Operation 805 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 mTorr.

Benefits of the present disclosure include reliable gas activation (such as at relatively low processing temperatures); adjustability of gas activation; modularity of using plasma operations and epitaxial deposition operations in a single chamber; modularity in chamber application; more uniform gas activation; temperature uniformity (e.g., temperature uniformity in an outer region of the substrate); reduced gas consumption and gas waste; increased growth rates; and more uniform film growth and/or dopant concentration. As an example, ions and/or radicals can be used to activate gases for processing in addition to or in place of electromagnetic radiation (such as infrared radiation and/or ultraviolet radiation).

Benefits also include enhanced device performance; reduced or eliminated occurrences of unintended dopant diffusions; efficient processing; and increased throughput. As an example, the gas activation is facilitated for substrate target temperatures less than 500 degrees Celsius, such as target temperatures within a range of 380 degrees to 500 degrees Celsius. For example, gas can be activated for processing operations when the substrate is at about 400 degrees Celsius.

It is contemplated that one or more aspects disclosed herein may be combined. As an example, one or more aspects, features, components, operations and/or properties of the processing chamber 100; the flow module 112, the flow housing 171, the one or more RF coils 172, the gas source 158, the RF power source 180, the first electrode 181, the second electrode 182, the conductive rod 183, the processing chamber 200, the magnet sets 290A, 290B, 290C, the actuators 201A, 201B, 201C, the actuator supports 202A, 202C, the processing chamber 300, the magnet sets 390A, 390B, the processing chamber 400, the magnet sets 490A, 490B, the processing chamber 500, the magnet set 590, the lid assembly 510, the inner wall 512, the outer wall 511, the one or more gas inlets 520, the processing chamber 600, the magnet sets 690A, 690B, the magnet set 790, the magnetic ring 780 and/or the method 800 may be combined. The present disclosure contemplates that the one or more coils 172 can be disposed in a variety of positions that can differ from those shown in FIGS. 1-6. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for semiconductor manufacturing, comprising:
one or more sidewalls;
a plate at least partially defining a processing volume;
a substrate support disposed in the processing volume;
one or more heat sources operable to heat the processing volume;
a first electrode disposed outwardly of the processing volume; and
a second electrode coupled to the substrate support.

2. The processing chamber of claim 1, further comprising:
a radio frequency (RF) power source electrically coupled to the first electrode; and
a conductive rod electrically coupled to the second electrode.

3. The processing chamber of claim 1, wherein the first electrode is disposed at a gap from the plate, and the second electrode is embedded in the substrate support.

4. The processing chamber of claim 1 further comprising:
a flow housing disposed at least partially outwardly of the one or more sidewalls; and
one or more (RF) coils disposed at least partially around the flow housing.

5. A processing chamber applicable for semiconductor manufacturing, comprising:
one or more sidewalls;
a plate at least partially defining an processing volume;
a substrate support disposed in the processing volume;
one or more heat sources operable to heat the processing volume; and
a plurality of magnets configured to generate a magnetic field across at least a section of the processing volume.

6. The processing chamber of claim 5, wherein the plurality of magnets comprises a first magnet set and a second magnet set, the first and second magnet sets respectively comprising a plurality of curved sections.

7. The processing chamber of claim 5, wherein at least one of the plurality of magnets comprises a magnetic ring.

8. The processing chamber of claim 5, wherein at least one of the plurality of magnets is coupled to one or more actuators operable to move the respective magnet.

9. The processing chamber of claim 5, further comprising:
a flow housing disposed at least partially outwardly of the one or more sidewalls; and
one or more (RF) coils disposed at least partially around the flow housing, wherein at least one of the plurality of magnets is disposed at least partially about the flow housing.

10. The processing chamber of claim 5, further comprising:
a lid assembly, the lid assembly comprising:
an outer wall;
an inner wall; and
one or more magnets disposed at least partially around the lid assembly.

11. The processing chamber of claim 10, wherein the magnets comprise a plurality of second magnets disposed inwardly of the inner wall.

12. The processing chamber of claim 10, wherein the lid assembly further comprises:
a gas inlet; and
one or more RF coils disposed out least partially about the outer wall.

13. The processing chamber of claim 5, wherein the magnetic field is about curved.

14. The processing chamber of claim 5, wherein the plurality of magnets are configured to generate a magnetic field that is angled relative to a gas flow path.

15. The processing chamber of claim 5, wherein the plurality of magnets are disposed at least partially about the plate and a window, and the plurality of magnets are operable to generate the magnetic field across at least a section of the processing volume.

16. The processing chamber of claim 5, wherein the plurality of magnets comprise one or more first magnets and one or more second magnets disposed radially outwardly of the one or more first magnets.

17. A method of substrate processing, comprising:
heating a substrate positioned on a substrate support to a target temperature, the substrate disposed in a processing volume;
flowing one or more process gases over the substrate;
flowing a gas to the processing volume; and
applying a power to the processing volume while flowing the gas to generate a plasma.

18. The method of claim 17, wherein the power is applied across the processing volume between a first electrode and a second electrode coupled to the substrate support.

19. The method of claim 17, wherein a magnetic field is generated across at least part of the plasma.

20. The method of claim 19, wherein the magnetic field is angled relative to a gas flow path of the gas.
